(19) United States
(12) Patent Application Publication
(10) Pub. No.: US 2026/0255487 A1
(43) Pub. Date: Aug. 27, 2026

(54) STACKED BOARD AND COMPUTER DEVICE EMPLOYING BOARD

(71) Applicants: HON HAI PRECISION INDUSTRY CO., LTD., New Taipei (TW); HONGFUJIN PRECISION INDUSTRY (WUHAN) CO., LTD., Wuhan (CN)

(72) Inventors: HOU-YUAN CHOU, New Taipei (TW); SHEN-FA TSAI, New Taipei (TW); YI-CHIH WU, New Taipei (TW); PING-YING LEE, New Taipei (TW); FENG-HUA DENG, Wuhan (CN)

(21) Appl. No.: 18/863,979

(22) PCT Filed: Jul. 19, 2023
(86) PCT No.: PCT/CN2023/108083

§ 371 Date: Nov. 7, 2024

(51) Int. Cl. H05K 1/14

(52) U.S. Cl. CPC H05K 1/147; H05K 1/141; H05K 2201/10325

(57) ABSTRACT

A stacked board includes: a motherboard and a flexible circuit board. The motherboard includes a connection assembly and at least two slots, the connection assembly includes at least two electrical connectors, the slots and the electrical connectors are coupled through high-speed signal lines arranged on the motherboard, the slots are configured for installing electronic devices, and high-speed signals are transmitted between the electronic devices through the high-speed signal lines and the electrical connectors. The flexible circuit board is electrically connected with the motherboard through the connection assembly, at least one electrical connector of the connection assembly transmits the high-speed signals to the flexible circuit board, and the flexible circuit board is configured to transmit the high-speed signals to an objective electrical connector of the connection assembly that is coupled to an electronic device for receiving the high-speed signals. A computer device is also provided.

### TECHNICAL FIELD

This application relates to the field of printed circuit board (PCB) technologies, and specifically, relates to a stacked board and a computer device.

### BACKGROUND

A motherboard may also known as a system board or a main board. The motherboard is a core of a computer hardware system, and is the largest printed circuit board in a main chassis. The main function of the motherboard is configured to transmit various electronic signals. Electronic devices are arranged on the motherboard to form a computer mainframe, the motherboard may include an input/output (I/O) control chip and a plurality of slots, such as panel control switch slots, peripheral component interface express (PCIE) graphics card slots, indicator slots, expansion slots, direct current (DC) power supply slots for the motherboard or other card, etc.

Among the electronic devices arranged on the motherboard, some electronic devices need to transmit high-speed signals to each other. In order to ensure a transmission of high-speed signals on the motherboard, the motherboard needs to be manufactured by a high-specification printed circuit board (PCB), for example, the high-specification PCB for manufacturing the motherboard may use low-loss materials, and the use of low-loss materials may cause a high cost of the motherboard.

### SUMMARY

Accordingly, it is necessary to provide a stacked board that can reduce the cost of the motherboard and further ensure a transmission of high-speed signals between electronic devices arranged on the motherboard.

First aspect of this application provides a stacked board, the stacked board includes a motherboard and a flex circuit board. The motherboard includes a connection assembly and at least two slots, the connection assembly includes at least two electrical connectors, the at least two slots and the at least two electrical connectors are coupled through high-speed signal lines arranged on the motherboard, the slots are configured for installing electronic devices, and high-speed signals are transmitted between the electronic devices through the high-speed signal lines and the electrical connectors. The flex circuit board is coupled to the motherboard through the connection assembly, at least one electrical connector of the connection assembly transmits the high-speed signals to the flexible circuit board, and the flexible circuit board is configured to transmit the high-speed signals to an objective electrical connector of the connection assembly that is coupled to an electronic device for receiving the high-speed signals.

The stacked board of the embodiment of the present application includes the motherboard and the flexible circuit board externally connected to the motherboard, in the stacked board, the flexible circuit board is used to transmit high-speed signals for each electronic device arranged on the motherboard, the flexible circuit board has a good transmission performance of high-speed signals, the transmission of high-speed signals between the electronic devices on the motherboard can be guaranteed, and the motherboard can not adopt a PCB of high-cost materials, the cost of the motherboard can be reduced.

In one embodiment, the stacked board further includes a conductive rubber, the flexible circuit board is in contact with a side of the conductive rubber, and the objective electrical connector is in contact with another side of the conductive rubber, the conductive rubber is configured for electrically connecting the flexible circuit board and the objective electrical connector to transmit the high-speed signals.

The embodiment of the present application adopts the conductive rubber, the conductive rubber is a kind of soft conductive rubber, the conductive rubber can not only ensure the electrical connection between the motherboard and the flexible circuit board, but also can play a buffering protection role between the motherboard and the flexible circuit board in a case of impact, dropping, etc., so that the flexible circuit board can be flatly fitted to the motherboard, and a board bending phenomenon is reduced.

In one embodiment, the flex circuit board includes first pads, the flexible circuit board is in contact with the side of the conductive rubber through the first pads.

In one embodiment, the objective electrical connector includes at least one second pad.

In one embodiment, the objective electrical connector includes at least one solder ball.

In one embodiment, the motherboard is stacked with the flexible circuit board, a fixed plate is arranged on the flexible circuit board, and the fixed plate is arranged on a surface of the flexible circuit board that deviates from the motherboard.

The embodiment of the present application can reduce the bending phenomenon of the flexible circuit board by arranging the fixed plate on the flexible circuit board.

In one embodiment, the stacked board includes fasteners, each of the fixed plate, the flexible circuit board, and the motherboard is provided with drilled holes, and the fasteners pass through the drilled holes arranged on the fixed plate, the flexible circuit board, and the motherboard to fasten and connect the fixed plate, the flexible circuit board, and the motherboard.

The embodiment of the present application can accurately position the electrical connector of the motherboard to the flexible circuit board through the fixed plate and the fasteners.

In one embodiment, the at least two slots include a central processing unit (CPU) slot and a peripheral component interface express (PCIE) graphics card slot.

In one embodiment, the motherboard is manufactured by a middle loss board.

The motherboard of the embodiment of the present application adopts middle loss board, which can reduce the cost of the motherboard.

Second aspect of this application provides a computer device, the computer device includes the stacked board as recited in the above-mentioned.

### BRIEF DESCRIPTION OF THE DRAWINGS

FIG. 1 is a schematic structural diagram of a stacked board including signal transmission direction according to an embodiment of the present application;

FIG. 2 is a schematic structural diagram of electrical connectors of the stacked board being solder balls according to an embodiment of the present application;

FIG. 3 is a partial enlarged structure diagram of the stacked board of FIG. 2 according to an embodiment of the present application;

FIG. 4 is a schematic structural diagram of electrical connectors of the stacked board being pads according to an embodiment of the present application;

FIG. 5 is a partial enlarged structure diagram of the stacked board of FIG. 4 according to an embodiment of the present application.

Reference signs: motherboard 10; slot 11; PCIE graphics card slot 111; CPU slot 112; connection assembly 12; electrical connector 121, 122; solder ball 1211; second pad 1212; flexible circuit board 20; first pad 21; electronic device 30; PCIE graphics card 31; CPU 32; conductive rubber 40; fixed plate 50; fastener 60.

### DETAILED DESCRIPTION

The embodiments of the present application are illustrated by one or more specific embodiments, and those skilled in the art may understand other advantages and effects of the present application from the contents disclosed in the present embodiments. Although the description of the present application will be presented together with the specific embodiments, this does not mean that the features of the application are limited to the specific embodiments. On the contrary, the purpose of the presentation of the application in conjunction with the embodiments is to cover other options or modifications that may be extended based on claims of the present application. In order to provide an in-depth understanding of this application, many specific details will be included in the following description. This application may also be implemented without the use of these details. In addition, in order to avoid confusion or obscurity of the focus of this application, some specific details will be omitted from the description. It should be noted that, the embodiments in the present application and the features in the embodiments may be combined with each other.

The following, if used, the terms “first”, “second”, etc., are used for descriptive purposes only and should not be construed as indicating or implying relative importance or implying the number of technical features indicated. Thus, defining features such as “first”, “second”, etc., may explicitly or implicitly include one or more of these features. In the description of this application, unless otherwise stated, “multiple” or “a plurality of” means two or more. Orientation terms such as “up”, “down”, “left”, “right” are defined in relation to the orientation of the parts in the drawing, and it should be understood that these directional terms are relative concepts, and they are used for the description and clarification of the relative position, which can be changed according to the change in the orientation of the parts placed in the drawing.

In the present application, unless otherwise expressly specified and qualified, the term “connected” or “coupled” shall be construed broadly, for example, the term “connected” or “coupled” may be a fixed connection, a detachable connection, or a single unit; It can be directly connected or indirectly through an intermediate element. As used herein, the term “and/or” includes any and all combinations of one or more related listed items.

One or more electronic devices are arranged on a motherboard for implementing data processing functions of a computer. A main function of the motherboard includes transmitting a plurality of electronic signals. If at least two electronic devices arranged on the motherboard, such as the at least two electronic devices include a peripheral component interface express (PCIE) graphics card and a central processing unit (CPU), high-speed signals need to be transmitted between the PCIE graphics card and the CPU, high-speed signal lines arranged on the motherboard need to connect two ends of corresponding slots of the two electronic devices, so that the high-speed signal can be transmitted from one electronic device to another electronic device through the high-speed signal lines on the motherboard.

In the above case, in order to enable the motherboard to transmit the high-speed signals smoothly, materials of the motherboard generally use low-loss materials, and the use of low-loss materials may lead to a high cost of the motherboard.

Moreover, connecting different electronic devices at both ends of the high-speed signal lines may cause a trace length of the high-speed signal lines on the motherboard to be longer, and other electronic components that are arranged on the motherboard may also block the high-speed signal lines, resulting in a bending of the high-speed signal lines is complex, and a layout design of the motherboard is more difficult, and it may also cause a loss of high-speed signal transmission to be larger.

In view of the above, the embodiment of the present application provides a stacked board. In order to make the purpose, technical solution and advantages of the present application clearer, the stacked board in the embodiment of the present application will be described in further detail below in conjunction with the accompanying drawings.

When the following embodiments are described in detail in conjunction with the accompanying drawings, for the sake of convenience, the diagram representing the local structure of the components will be partially enlarged in accordance with the general proportion, and the diagram is only an example, and the scope of the present application for protection shall not be limited herein.

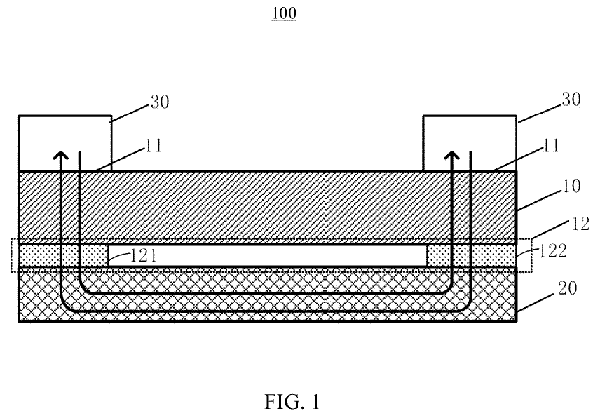

FIG. 1 is a structural diagram of the stacked board according to an embodiment of the present application.

The stacked board includes a motherboard 10 and a flexible circuit board 20 externally coupled to the motherboard 10.

The motherboard 10 includes at least two slots 11, and the slots 11 can also be defined as interfaces of the motherboard 10. The slots 11 are configured for installing electronic devices 30, so that the electronic devices 30 can be electrically connected with the motherboard 10. For example, the two slots 11 may include a PCIE graphics card slot and a CPU slot.

The motherboard 10 is also provided with a connection assembly 12, and the connection assembly 12 may include at least two electrical connectors, such as an electrical connector 121 and an electrical connector 122.

The slot 11 is electrically connected with the electrical connector through the high-speed signal lines on the motherboard 10, so that the electronic device 30 installed in the slot 11 can transmit high-speed signals to the electrical connector through the high-speed signal lines.

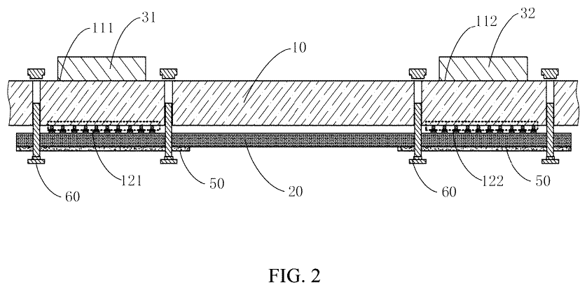

For example, as shown in FIG. 2, the PCIE graphics card slot 111 and the electrical connector 121 are electrically connected through a part of high-speed signal lines, and the CPU slot 112 and the electrical connector 122 are electrically connected through other part of high-speed signal lines.

The electrical connector of the connection assembly 12 can encapsulate the high-speed signal lines on the motherboard 10, and can transmit the high-speed signals on the high-speed signal lines on the motherboard 10 to the flexible circuit board 20, and the high-speed signals can also be transmitted from the flexible circuit board 20 to the motherboard 10.

The flexible circuit board 20 is electrically connected with the motherboard 10 through the connecting assembly 12. At least one electrical connector (such as an electrical connector 121) exists in the connection assembly 12 for receiving the high-speed signals from a slot 11 through the high-speed signal lines, and transmits the high-speed signals to the flexible circuit board 20. High-speed signal lines are also arranged on the flexible circuit board 20, the high-speed signal line arranged on the flexible circuit board 20 are configured for transmitting the high-speed signals received from one electrical connector (such as the electrical connector 121) to another electrical connector (such as the electrical connector 122) that is electrically connected with another electronic device for receiving the high-speed signals.

For example, the electronic device 30 used for receiving the high-speed signals is defined as the objective electronic device, a slot for installing the objective electronic device is defined as the objective socket, an electrical connector that is connected with the objective socket through the high-speed signal lines is defined as the objective electrical connector, and the objective electrical connector is an electrical connector of the connection assembly 12 that is electrically connected with the objective electronic device for receiving the high-speed signals.

The high-speed signals can be signals with a data transmission rate not less than a preset threshold, the preset threshold can be set according to application scenarios of the high-speed signals, signal transmission standards, or signal transmission protocols.

For example, the preset threshold is 32 gigabits per second (Gbps). For example, signals transmitted by USB3 (super speed USB) and PCIE-GEN5 (fifth generation PCIE) can also be regarded as high-speed signals.

In the stacked board, a transmission direction of high-speed signals can be an arrow as shown in FIG. 1, and the high-speed signals can be transmitted from the motherboard 10 to the flexible circuit board 20 through the high-speed signal lines. Therefore, when an electronic device arranged on the motherboard 10 needs to transmit the high-speed signals to another electronic device arranged on the motherboard 10, the high-speed signals are not transmitted from an electronic device to another electronic device only by the high-speed lines arranged on the motherboard 10, the transmission of the high-speed signals is further realized through the flexible circuit board 20 externally connected with the motherboard 10. It can not only save the space of the motherboard 10, facilitate the layout of electronic components, such as slots on the motherboard 10, improve the flexibility of design of the motherboard 10, but also reduce the transmission loss of high-speed signals on the motherboard 10, and simplify the layout complexity of the high-speed signal lines.

In addition, even if the motherboard 10 is not manufactured from a single expensive high-specification printed circuit board (PCB), and transmission requirements of high-speed signals of the motherboard 10 can be met, which is convenient to reduce the cost of the motherboard 10 that can transmit high-speed signals. For example, the PCB for manufacturing the motherboard 10 of the embodiment of the present application can be middle loss materials, and low loss materials are not required.

In one embodiment, a board grade of the PCB can be divided according to a dissipation factor (DF).

Different substrate materials can be divided into a standard loss, a middle loss, a low loss, a very low loss, an ultra low loss according to the dissipation factor of the substrate, and the dissipation factor corresponding to each type of board can be shown in Table 1.

TABLE 1

| Board | Standard | | | Very Low | Ultra Low |
|---|---|---|---|---|---|
| Type | Loss | Middle Loss | Low Loss | Loss | Loss |
| DF | 0.015~0.020 | 0.010~0.015 | 0.0065~0.01 | 0.003~0.0065 | <0.003 |

It is can be understandable that the dissipation factor corresponding to each type of board is only an example, and with the change of the board loss standard, the dissipation factor corresponding to each type of board can also be changed, and the embodiment of the present application does not limit this.

The smaller the dissipation factor of the board, the higher the cost of the board. In one embodiment of the present application, the integrated circuit board of the motherboard adopts the middle loss board and can transmit the high-speed signals between at least two electronic devices arranged on the motherboard, and the cost of the motherboard can be reduced compared with the integrated circuit board of the motherboard using the low-loss board.

The slot 11 provided with the above-mentioned motherboard may be a hardware slot, a power slot, a chassis front slot, etc., but is not limited to.

The hardware slot may include: a CPU slot, a memory slot, a PCIE graphics card slot, a M.2 (next generation form factor) slot, a serial advanced technology attachment (SATA) slot, a fan slot, etc.

The power slot may include: a CPU power supply slot, a motherboard power supply slot, a PCIE power supply slot, etc.

The chassis front slot may include: a power-on/restart button and hard disk indicator slot, a USB2.0 slot, a USB3.0 slot, an audio slot, etc.

A rear input/output (I/O) slot may include: a USB slot, a video slot, a network cable slot, an audio slot, etc., but is not limited to.

Each slot can install an electronic device matched with the type of the slot, such as a CPU slot for installing the CPU, a M.2 slot for installing the M.2 solid state disk (SSD), a SATA slot for installing the SATA SSD, a PCIE graphics card slot for installing the PCIE graphics card, etc.

For example, the electronic devices installed in at least two slots of the motherboard 10 have requirements to transmit high-speed signals to each other.

For example, as shown in FIG. 2, the at least two slots of the motherboard 10 include the PCIE graphics card slot 111 and the CPU slot 112. The PCIE graphics card slot 111 is installed with the PCIE graphics card 31, and the CPU slot 112 is installed with the CPU 32, and transmission requirements of the high-speed signals are existed between the PCIE graphics card 31 and the CPU 32.

Each slot 11 on the motherboard 10 and each electrical connector on the motherboard 10 can be electrically connected one by one through high-speed signal lines.

For example, referring to FIG. 2, the electrical connector 121 is electrically connected to the PCIE graphics card slot 111 through the high-speed signal lines, which enables the PCIE graphics card 31 to transmit high-speed signals to the electrical connector 121 through the PCIE graphics card slot 111, or, the electrical connector 121 transmits high-speed signals to the PCIE graphics card slot 111 through the high-speed signal lines, and then the high-speed signal can be transmitted to the PCIE graphics card 31.

The electrical connector 122 is electrically connected with the CPU slot 112 through high-speed signal lines, so that the CPU 32 can transmit high-speed signals to the electrical connector 122 through the CPU slot 112, or the electrical connector 122 transmits the high-speed signals to the CPU slot 112 through the high-speed signal lines, and the CPU slot 112 transmits the high-speed signals to the CPU 32.

In one embodiment, one end of the high-speed signal lines is electrically connected with the slot, and another end of the high-speed signal lines is electrically connected or packeted in the electrical connector, so that on the surface of the motherboard, the high-speed signal lines can form an electrical connection with the flexible circuit board 20 through the electrical connector, and the high-speed signals can be transmitted between the motherboard 10 and the flexible circuit board 20.

In one embodiment, each electrical connector of the connection assembly may be a cable connector.

However, fewer cable connectors are arranged on the motherboard, and if the number of cable connectors increases, the cost of the motherboard may also increases.

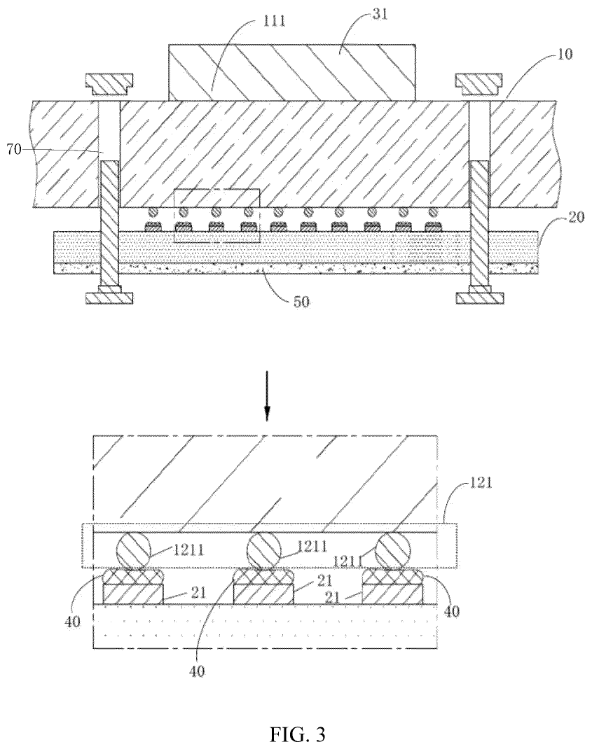

Referring to FIG. 2 and FIG. 3, in one embodiment, each electrical connector of the connection assembly may include at least one solder ball 1211.

If the high-speed signals of the electronic devices need to be transmitted through a plurality of high-speed signal lines, each electrical connector arranged on the motherboard may include a plurality of solder balls 1211, and each solder ball 1211 is electrically connected to one high-speed signal line.

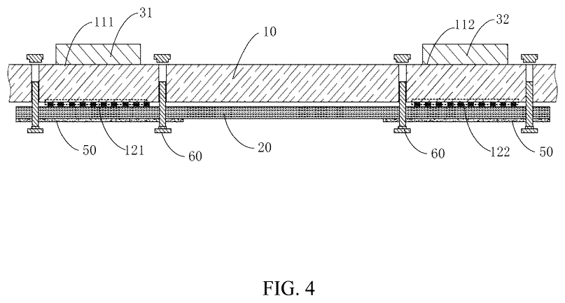

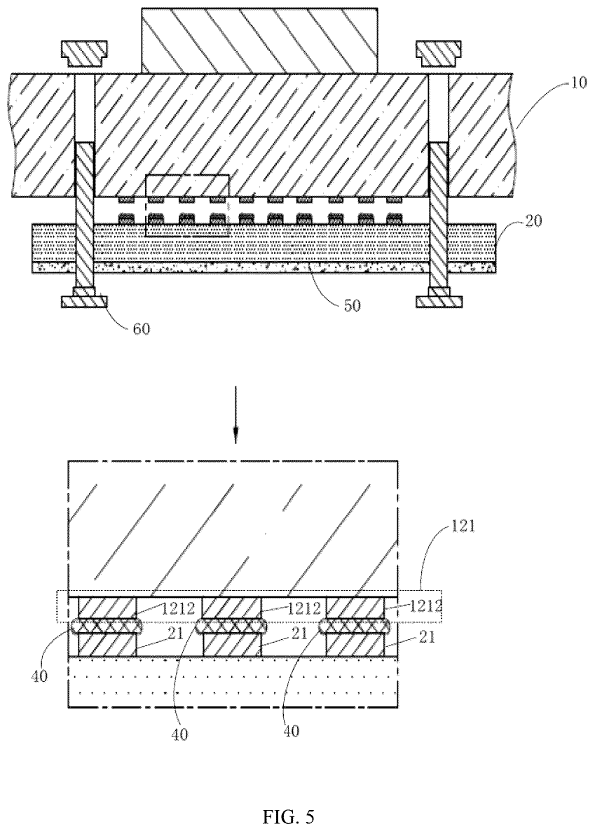

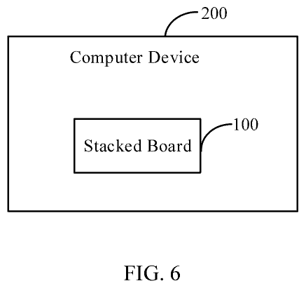

In one embodiment, as shown in FIG. 4 and FIG. 5, each electrical connector arranged on the motherboard 10 may include at least one second pad 1212.

If the high-speed signals of the electronic devices need to be transmitted through a plurality of high-speed signal lines, each electrical connector arranged on the motherboard may include a plurality of second pads 1212, and each second pad 1212 is electrically connected to one high-speed signal line.

Compared with the motherboard being connected with the flexible circuit board 20 through a cable connector, in one embodiment of the present application, a solder ball or a second pad can be arranged on the motherboard 10, and the motherboard 10 is electrically connected with the flexible circuit board through the solder ball or the second pad, so that the cost of the motherboard can be reduced.

In one embodiment, referring to FIG. 3 and FIG. 5, the stacked board further includes a conductive rubber 40, the flexible circuit board 20 is in contact with one side of the conductive rubber 40, and the electrical connector is in contact with another side of the conductive rubber 40. The conductive rubber 40 is configured for electrically connecting the flexible circuit board 20 and the electrical connector, so that the flexible circuit board 20 can be electrically connected with the motherboard 10.

The conductive rubber 40 is a kind of soft rubber, and the soft rubber can be doped with conductive particles such as gold powder, silver powder, copper powder, etc.

Because the conductive rubber 40 is a kind of soft conductive rubber, and the embodiment of the present application can adopt the conductive rubber 40 as contact points between the motherboard 10 and the flexible circuit board 20. The conductive rubber 40 can not only ensure an electrical connection between the motherboard 10 and the flexible circuit board 20, but also play a buffering protection role between the motherboard 10 and the flexible circuit board 20 in a case of impact, dropping, etc., so that the flexible circuit board 20 can be flatly fitted to the motherboard 10, and a board bending phenomenon is reduced.

Furthermore, in one embodiment, a plurality of first pads 21 is arranged on the flexible circuit board 20, and the flexible circuit board 20 contacts the conductive rubber 40 through the plurality of first pads 21.

The embodiment refers that the plurality of first pads 21 is arranged on the flexible circuit board 20 to facilitate an electrical connection between the flexible circuit board and the motherboard.

Because the flexible circuit board 20 can transmit high-speed signals, the flexible circuit board 20 can also be provided with high-speed signal lines, one end of the high-speed signal lines arranged one the flexible circuit board 20 can be electrically connected to a part of first pads 21, the part of first pads 21 are electrically connected to the electrical connector 121, another end of the high-speed signal lines arranged one the flexible circuit board 20 can be electrically connected to the other part of first pads 21, and the other part of first pads 21 are electrically connected with the electrical connector 122, to enable the high-speed signals to be transmitted on the flex circuit board 20.

In one embodiment, the motherboard 10 and the flexible circuit board 20 are stacked, a fixed plate 50 is arranged on the flexible circuit board 20. The fixed plate 50 can be is arranged on a surface of the flexible circuit board 20 that deviates from the motherboard 10, for example, the fixed plate 50 can be arranged on two opposite ends of the surface. In the stacked board, the fixed plate 50 can be arranged on the flexible circuit board 20 through fixtures or other fixing devices, and the fixed plate 50 can also be arranged on the flexible circuit board 20 by other means, and the embodiment of the application does not limit this.

The present embodiment can reduce a board bending phenomenon of the flexible circuit board by installing the fixed plate 50 on the flexible circuit board 20.

Further, the stacked board may also include fasteners 60. Each of the fixed plate 50, the flexible circuit board 20, and the motherboard 10 is provided with drilled holes, and the fasteners 60 pass through the drilled holes arranged on the fixed plate 50, the flexible circuit board 20, and the motherboard 10, to achieve the fixed plate 50, the flexible circuit board 20, and the motherboard 10 being fastened and connected.

The embodiment of the application can further achieve a precise positioning of the flexible circuit board 20 and the motherboard 10 through the fixing plate 50 and the fasteners 60, so that the position of the first pads 21 are exactly opposite the position of the electrical connector of the motherboard 10.

The motherboard 10 of the embodiment of the present application is externally connected with the flexible circuit board 20, and the high-speed signals are transmitted through the flexible circuit board 20, the space of the motherboard can be saved, the arrangement of electronic components such as the slots 11 on the motherboard 10 are convenient, the flexibility of the position design of each electronic component on the motherboard is improved, the transmission loss of the high-speed signals on the motherboard 10 can also be reduced, the layout of high-speed lines is simplified, and the cost of the motherboard is also reduced.

In addition, the stacked board of the embodiment of the present application adopts the conductive rubber 40 as the contact points between the motherboard 10 and the flexible circuit board 20, the conductive rubber 40 can not only ensure the electrical connection between the motherboard 10 and the flexible circuit board 20, but also play a buffering protection role between the motherboard 10 and the flexible circuit board 20 in a case of impact, dropping, etc., the flexible circuit board 20 can be flatly fitted to the motherboard 10, and the board bending phenomenon is reduced.

The flexible circuit board 20 of the embodiment of the present application is in contact with the conductive rubber 40 through the first pads, and the motherboard 10 adopts the solder balls or the second pads to contact with the conductive rubber 40, so that the flexible circuit board 20 and the motherboard 10 can be electrically connected, and the manufacturing cost of the motherboard can be further reduced compared with the flexible circuit board 20 electrically connected with the motherboard 10 through one or more cable connectors.

An embodiment of the present application also provides a computer device. The computer device may includes the stacked board as recited in the above embodiment.

The above is only the specific embodiment of the present application, but the scope of protection of the present application is not limited to this, and any change or replacement within the technical scope disclosed in the application shall be covered by the scope of protection of the present application.

1. A stacked board, comprising:
a motherboard, comprising a connection assembly and at least two slots, wherein the connection assembly comprises at least two electrical connectors, the at least two slots and the at least two electrical connectors are coupled through high-speed signal lines arranged on the motherboard, the slots are configured for installing electronic devices, and high-speed signals are transmitted between the electronic devices through the high-speed signal lines and the electrical connectors; and
a flex circuit board coupled to the motherboard through the connection assembly, wherein at least one electrical connector of the connection assembly transmits the high-speed signals to the flexible circuit board, and the flexible circuit board is configured to transmit the high-speed signals to an objective electrical connector of the connection assembly that is coupled to an electronic device for receiving the high-speed signals.

2. The stacked board of claim 1, further comprising a conductive rubber, wherein the flexible circuit board is in contact with a side of the conductive rubber, and the objective electrical connector is in contact with another side of the conductive rubber, the conductive rubber is configured for electrically connecting the flexible circuit board and the objective electrical connector to transmit the high-speed signals.

3. The stacked board of claim 2, wherein the flex circuit board comprises first pads, the flexible circuit board is in contact with the side of the conductive rubber through the first pads.

4. The stacked board of claim 1, wherein the objective electrical connector comprises at least one second pad.

5. The stacked board of claim 1, wherein the objective electrical connector comprises at least one solder ball.

6. The stacked board of claim 1, wherein the motherboard is stacked with the flexible circuit board, a fixed plate is arranged on the flexible circuit board, and the fixed plate is arranged on a surface of the flexible circuit board that deviates from the motherboard.

7. The stacked board of claim 6, further comprising fasteners, wherein each of the fixed plate, the flexible circuit board, and the motherboard is provided with drilled holes, and the fasteners pass through the drilled holes arranged on the fixed plate, the flexible circuit board, and the motherboard to fasten and connect the fixed plate, the flexible circuit board, and the motherboard.

8. The stacked board of claim 1, wherein the at least two slots comprise a central processing unit (CPU) slot and a peripheral component interface express (PCIE) graphics card slot.

9. The stacked board of claim 1, wherein the motherboard is manufactured by a middle loss board.

10. A computer device, comprising a stacked board according to the stacked board comprising:
a motherboard, comprising a connection assembly and at least two slots, wherein the connection assembly comprises at least two electrical connectors, the at least two slots and the at least two electrical connectors are coupled through high-speed signal lines arranged on the motherboard, the slots are configured for installing electronic devices, and high-speed signals are transmitted between the electronic devices through the high-speed signal lines and the electrical connectors; and
a flex circuit board coupled to the motherboard through the connection assembly, wherein at least one electrical connector of the connection assembly transmits the high-speed signals to the flexible circuit board, and the flexible circuit board is configured to transmit the high-speed signals to an objective electrical connector of the connection assembly that is coupled to an electronic device for receiving the high-speed signals.

11. The computer device of claim 10, wherein the stacked board further comprises a conductive rubber, the flexible circuit board is in contact with a side of the conductive rubber, and the objective electrical connector is in contact with another side of the conductive rubber, the conductive rubber is configured for electrically connecting the flexible circuit board and the objective electrical connector to transmit the high-speed signals.

12. The computer device of claim 11, wherein the flex circuit board comprises first pads, the flexible circuit board is in contact with the side of the conductive rubber through the first pads.

13. The computer device of claim 10, wherein the objective electrical connector comprises at least one second pad.

14. The computer device of claim 10, wherein the objective electrical connector comprises at least one solder ball.

15. The computer device of claim 10, wherein the motherboard is stacked with the flexible circuit board, a fixed plate is arranged on the flexible circuit board, and the fixed plate is arranged on a surface of the flexible circuit board that deviates from the motherboard.

16. The computer device of claim 15, wherein the stacked board further comprises fasteners, each of the fixed plate, the flexible circuit board, and the motherboard is provided with drilled holes, and the fasteners pass through the drilled holes arranged on the fixed plate, the flexible circuit board, and the motherboard to fasten and connect the fixed plate, the flexible circuit board, and the motherboard.

17. The computer device of claim 10, wherein the at least two slots comprise a central processing unit (CPU) slot and a peripheral component interface express (PCIE) graphics card slot.

18. The computer device of claim 10, wherein the motherboard is manufactured by a middle loss board.
